(19) United States
(12) Patent Application Publication
(10) Pub. No.: US 2021/0036173 A1
(43) Pub. Date: Feb. 4, 2021

(54) STABILIZED SHINGLED SOLAR CELL STRINGS AND METHODS FOR THEIR PRODUCTION

(71) Applicant: MEYER BURGER (SWITZERLAND) AG, Gwatt/ Thun (CH)

(72) Inventors: Pierre PAPET, Hauterive (CH); Benjamin STRAHM, Giez (CH)

(21) Appl. No.: 16/631,551

(22) PCT Filed: Jul. 16, 2018
(86) PCT No.: PCT/EP2018/069209

§ 371 Date: Jan. 16, 2020

(30) Foreign Application Priority Data
Jul. 27, 2017 (EP) 17182319.8

(51) Int. Cl. H01L 31/048; H01L 31/02; H01L 31/05; H01L 31/18

(52) U.S. Cl. CPC H01L 31/0481; H01L 31/1876; H01L 31/0508; H01L 31/0201

(57) ABSTRACT

The present invention is directed to solar cell strings comprising (i) a string of solar cells shingled in string direction, resulting in positive and negative electrode overlap, (ii) an interconnect for electrically connecting the positive and negative electrodes of the shingled solar cells, and (iii) an adhesive foil spanning at least part of the string and positioned on (a) the top (sun facing) sides of the at least two shingled solar cells, and/or (b) the bottom (far) sides of the at least two shingled solar cells, or on (c) the top side of one solar cell and on the bottom side of the overlapping solar cell, in which case the adhesive foil comprises the interconnect and connects the overlap in order to mechanically connect and position the shingled solar cells. In addition, the present invention relates to a method for producing such solar cell strings.

The present invention is directed to solar cell strings comprising (i) a string of solar cells shingled in string direction, resulting in positive and negative electrode overlap, (ii) an interconnect for electrically connecting the positive and negative electrodes of the shingled solar cells, and (iii) an adhesive foil spanning at least part of the string and positioned on (a) the top (sun facing) sides of the at least two shingled solar cells, and/or (b) the bottom (far) sides of the at least two shingled solar cells, or on (c) the top side of one solar cell and on the bottom side of the overlapping solar cell, in which case the adhesive foil comprises the interconnect and connects the overlap in order to mechanically connect and position the shingled solar cells. In addition, the present invention relates to a method for producing such solar cell strings.

Typically, a photovoltaic module is assembled from a number of individually produced and separately transported solar cell strings, i.e. solar panels, and the strings are arranged side by side to form one large flat body. The solar cells of the string are electrically interconnected by wires or ribbons that connect the positive electrode side of one cell with the negative electrode side of the adjacent cell, thus allowing for current flow in string direction. Solar strings with solar cells arranged in parallel regularly feature a front-front configuration, where all front sides of the cells have the same electrode charge and the wire or ribbon will connect the front electrode of one cell with the rear electrode of opposite charge of the adjacent cell.

Alternatively, solar cell strings can be arranged in front-rear configuration in order to provide an overlap of adjacent front and rear electrodes, thus allowing direct conductive contact of adjacent cells. Shingled solar cell strings have reduced wiring requirements over the front-front arrangement.

Overlapping shingled solar cell strings do not need conventional wire or ribbon interconnectors because of the close proximity of oppositely charges cell electrodes. Mechanical and conductive contact is routinely achieved by adding low resistance electrically conductive interconnect materials such as conductive adhesive alloys. The metallization interconnect is often rather thick to improve current flow. Since the gap for electrical insulation between front-front-arranged solar cells is no longer required, solar modules with shingled front-rear-arranged solar cells can be dimensioned smaller in string direction.

However, mechanical stress on the interconnect in the overlap of shingled solar cells has the potential for (micro)cracks, possibly leading to reduced current flow or even short-circuiting due to thermocycling or during handling for manufacturing of the strings or when mounting the module. A further disadvantage of solar cell shingling is that the overlap part is no longer available for current formation. However, many solar cells feature a narrow rim region that is little or not photovoltaically active. Hence, loss of efficacy in shingled solar cell strings is typically less than proportional to the overlap surface size.

It is the objective of the present invention to provide conductively efficient and mechanically stable solar cell strings for use in the assembly of photovoltaic modules, which are easy to transport and handle for module production without damaging the string, in particular conductively efficient and mechanically stable shingled solar cell strings. It is a further objective of the present invention to provide for an efficient method for producing stable shingled strings of solar cells.

In a first aspect of the invention the objective is solved by a solar cell string for use in a photovoltaic module, the string comprising
(i) a string of at least two solar cells shingled in string direction, resulting in positive and negative electrode overlap,
(ii) at least one interconnect for electrically connecting the positive and negative electrodes of the shingled solar cells,
(iii) at least one adhesive foil spanning at least part of the string and positioned on
   a. the top (sun facing) sides of the at least two shingled solar cells, and/or
   b. the bottom (far) sides of the at least two shingled solar cells, or on
   c. the top side of one solar cell and on the bottom side of the overlapping solar cell, in which case the adhesive foil comprises the at least one interconnect and connects the overlap,

thereby mechanically connecting and positioning the shingled solar cells of the string.

The term “solar cell string” as defined herein, encompasses all mechanical and conductive arrangements of more than one solar cell that generates and transports a photovoltaically generated current along adjacently positioned solar cells in string direction, i.e. in the direction of current flow from the solar cell on one end to the solar cell on the opposite end.

The solar cell strings of the present invention are for use in a photovoltaic module, i.e. for assembling and forming part of a functional photovoltaic module. In a preferred embodiment, the solar cells for use in the present invention are conventional, e.g. with a semiconductor material positioned between top and bottom surfaces, e.g. anode and cathode materials, i.e. positive and negative electrodes, that may, for example, be formed by metallization or a transparent conductive coating, e.g. a transparent film coating.

The solar cells in the string of the present invention are shingled like roof shingles, i.e. arranged in serial contact but shifted to provide a partially overlapping contact region at the edges of neighboring cells. The overlapped edge region is preferably minimized to avoid loss of photovoltaic activity due to shading but sufficient in size to allow for stable conductive contact in the resulting solar module.

In the string of the invention, the solar cells are shingled in an alternating front-rear configuration of the electrodes, i.e. anode and cathode sides of the solar cells, resulting in the positive and negative overlap of the electrodes, which allows current flow along shingled solar cells.

In the string of the present invention the interconnect for electrically connecting the positive and negative electrodes of the shingled solar cells may be any material serving said function. For example, the interconnect may be an electrically conductive solder, adhesive, glue or adhesive foil, preferably a thermoadhesive electrically conductive solder, adhesive, glue or foil, more preferably selected from the group consisting of Ag-, Sn-, SnBi-, In-comprising solder, metal wires coated with solderable material, and adhesive foils comprising electrically conductive elements, preferably metal wires. For example, the interconnect may be in the form of metallization, e.g. a low melting conductive solder, a ribbon or wire(s).

In a preferred embodiment for practicing the present invention, the overlap of the string of solar cells comprises a non- or less photovoltaically active zone of at least two solar cells, if these solar cells feature non- or less photovoltaically active zones at the edge.

For common rectangular, most often square solar cells the overlap area for the interconnect is typically elongated. The overlap region can be used to form the interconnect material into a busbar for receiving the current from the collecting fingers of the solar cell.

In a further embodiment of the solar cell string of the present invention the interconnect is a or forms part of a busbar receiving solar cell fingers arranged in string direction, preferably receiving 2 to 20 solar cell fingers per cm, more preferably 5 to 15 solar cell fingers per cm.

The solar cell fingers for use in the present invention can also be arranged perpendicular to the string direction and/or may be arranged in a zig-zag or L-shaped pattern, e.g. in order to increase the size of the contacting area of the finger(s) with the electrode(s). Furthermore, in certain embodiments, the solar cell fingers are not connected to each other and/or are not connected to a busbar.

The adhesive foil for use in the solar cell string of the present invention spans at least part of the string, a part sufficiently large to mechanically and stably connect and position the shingled solar cells in the string—even if the solar cells are not yet connected with the interconnect(s). For example, in some embodiments the adhesive foil only spans the overlap area and, e.g. 1 to 10 mm next to the overlap of each solar cell. In another preferred embodiment the adhesive foil spans at least two neighboring cells substantially completely or even more preferred the whole string from one end to the other, thus covering all solar cells in between. This allows for an efficient production method, wherein the shingled overlapping solar cells are arranged in a row on top of the adhesive foil or the adhesive foil is arranged on top of a row of pre-arranged shingled solar cells, which allows for the continuous production on an assembly line. And if the shingled cells positioned on the adhesive foil are not (yet) connected by the interconnects that could form a rigid connection, the string is more elastic and easier to transport and handle, with the cells in the string already taking their final relative position, in particular, when the string is placed on a relatively flat surface. The adhesive foil can be any foil suitable to permanently fixate the shingled solar cell arrangement. For example, it can be self-adhesive or it may be melted or charged electrostatically to adhere to the cells. The adhesive foil can be a polymer or a non-polymer foil, e.g. a glass-, paper- or mineral-based foil. Also, the adhesive foil may comprise more than one type of foil or comprise more than one foil layer, e.g. a polymer layer and a glass or paper layer, or the foil, e.g. a non-polymer foil, is provided with an additional adhesive glue.

In a preferred but non-limiting embodiment, the adhesive foil is or comprises a polymer foil, preferably selected from the group consisting of duroplasts, preferably EVAs (ethylene vinyl acetates), TPSEs (thermoplastic silicone elastomers), TPUs (thermoplastic polyurethanes), PETs (polyethylene terephthalates), TPOs (thermoplastic polyfin elastomers), ionomers, thermoplasts; preferably PVBs (polyvinylbutyrals), silicones, polyolefins (PO), PPs (polypropylenes); and combinations of thermoduoplasts, more preferably a polymer foil thermoadhesive at temperatures in the range of 50 to 250° C., preferably in the range of 60 to 200° C., more preferably in the range of 75 to 175° C.

Thermoadhesive foils are preferred because they allow for easier positioning of the solar cells before heat application. Furthermore, in case of a thermoadhesive interconnect material, for example, a thermoadhesive electrically conductive solder, adhesive, glue or foil, the thermoadhesive foil and the interconnect can be connected to the solar cells simultaneously, thus saving process time.

For preparing the solar cell string of the present invention the adhesive foil can be positioned on the top (sun facing) sides of the shingled solar cells (see FIG. 2 below), and/or on the bottom (far) sides of the at least two shingled solar cells (see FIG. 3 below).

In an alternative embodiment the adhesive foil is positioned on the top side of one solar cell and on the bottom side of the overlapping solar cell (see FIG. 4), wherein the adhesive foil comprises at least one electrically conductive element, preferably a metal wire, for transporting current from one solar cell to the adjacent cell.

When the adhesive foil is positioned on the top side of solar cells and covers photovoltaically active surface of the solar cells, the polymer foil is preferably transparent for sun light, at least transparent for the light wavelengths required for photovoltaic current generation.

In a further aspect, the present invention relates to a method for the production of a solar cell string as described above, comprising the steps of:
(a) providing at least one adhesive foil,
(b) providing at least two solar cells comprising overlap regions for forming a shingled solar cell string,
(c) providing an interconnect material for electrically connecting the positive and negative electrodes of the shingled solar cells,
(d) positioning and connecting a first solar cell to the adhesive foil,
(e) positioning and connecting the interconnect material on a first electrode region of the first solar cell,
(f) positioning and connecting a second solar cell to the adhesive foil in string direction so that the first and second solar cells overlap in shingle arrangement, resulting in positive and negative electrode overlap,
(g) optionally positioning and connecting the interconnect material on a further electrode region of the second or further solar cell and positioning and connecting a third or further solar cell to the adhesive foil in string direction so that the first, second and further solar cells all overlap in shingle arrangement resulting in positive and negative electrode contact,
(h) electrically connecting the positive and negative electrodes of the shingled solar cells, preferably in the overlap regions, of the first, second or further solar cells during or after step (f) or during or after optional step (g).

Step (h) provides for two options when to electrically connect the positive and negative electrodes of adjacent shingled solar cells with the interconnect material, either at the same time as the foil is connected, or at a later time, e.g. after transfer, storage, transport, handling and/or assembly of the photovoltaic module. The latter option bears a clear advantage because it leaves the produced string with foil-based flexibility that would be lost if the string was positioned and held together by the interconnect material only.

In this regard, a preferred embodiment relates to the method of the present invention, wherein the shingled solar cell string prepared by steps (a) to (f) or (a) to (g) is electrically and preferably also mechanically connected, preferably in the overlap regions, at the time of assembly of a photovoltaic module, thus allowing for more flexibility for handling and transport until the time of assembly.

Preferably, the interconnect for use in the method of the present invention is an electrically conductive solder, adhesive, glue or adhesive foil, preferably a thermoadhesive electrically conductive solder, adhesive, glue or foil, more preferably selected from the group consisting of Ag-, Sn-, SnBi-, In-comprising solder, metal wires coated with solderable material, and adhesive foils comprising electrically conductive elements, preferably metal wires.

It is further preferred that the method of the present invention is one, wherein the shingling overlap comprises a non- or less photovoltaically active zone of the at least two solar cells.

In an alternative embodiment, the method of the present invention is one, wherein the interconnect is a or forms part of a busbar receiving solar cell fingers arranged in string direction, preferably receiving 2 to 20 solar cell fingers per cm, more preferably 5 to 15 solar cell fingers per cm. The solar cell fingers for use in the method of the present invention can also be arranged perpendicular to the string direction and/or may be arranged in a zig-zag or L-shaped pattern, e.g. in order to increase the size of the contacting area of the finger(s) with the electrode(s). Furthermore, in certain embodiments of the method of the present invention, the solar cell fingers are not connected to each other and/or are not connected to a busbar.

The adhesive foil for use in the method of the present invention is preferably one as described above for the solar cell strings.

In a preferred embodiment, the method of the present invention is one, wherein the adhesive foil is positioned on the top side of one solar cell and on the bottom side of the overlapping solar cell, wherein the adhesive foil comprises at least one, preferably more electrically conductive elements, preferably metal wires. Thus, the comprised electrically conductive elements can provide for the electrical connection, whereas the adhesive foil provides for mechanical positioning and fixation of the shingled solar cells.

In the following the present invention will be illustrated by representative examples and figures, none of which are to be interpreted as limiting the scope of the present invention beyond the appended claims.

List of reference signs

| | | | |
|---|---|---|---|
| (1) | photovoltaic module | (2) | string of shingled solar cells |
| (3a, 3b, 3c) | solar cells | (4) | shingled solar cell overlap |
| (5a, 5b) | interconnect | (6) | polymer foil |
| (7) | non- or less photovoltaic zone | (8a, 8b) | busbar or wire ribbon |
| (9) | solar cell fingers (current collector) | (10) | electrically conductive |
| (11) | solar cell string direction | | element, e.g. metal wire |

### FIGURES

FIG. 1 shows a conventionally shingled solar cell string (2) for use in the assembly of a photo-voltaic module (1) with mechanical stability resting solely on the interconnect (5a, 5b) bridging and connecting shingled solar cell overlap (4). Interconnect (5a) mechanically and electrically connects the positive electrode side of solar cell (3a) to the negative electrode side of solar cell (3b) and interconnect (5b) mechanically and electrically connects the positive electrode side of solar cell (3b) to the negative electrode side of solar cell (3c).

FIG. 2 shows a shingled solar cell string (2) for a photovoltaic module (1) according to FIG. 1 further comprising an adhesive foil (6) spanning the whole string (2) and positioned on top (sun facing) sides of the shingled solar cells (3a, 3b, 3c), thus providing additional mechanical stability, e.g. for handling, storage and transport of the string.

FIG. 2b shows an alternative embodiment of a shingled solar cell string (2) for use in the assembly of a photovoltaic module (1) according to FIG. 2, wherein the interconnects (5a, 5b) are already present but still incomplete, i.e. spaced apart, thereby allowing for more flexibility of the string (2) during handling, transport and assembly of a photovoltaic module on site but still keeping the solar cells (3a, 3b, 3c) stable in shingled positions. The incomplete interconnect (5) can be positioned on both or either side of the gap region (4) of the solar cells (3a, 3b, 3c).

FIG. 3 shows a shingled solar cell string (2) for use in the assembly of a photovoltaic module (1) according to FIG. 1, further comprising an adhesive foil (6) spanning the string (2) completely and positioned on bottom (far) sides of the shingled solar cells (3a, 3b, 3c), thus providing additional mechanical stability, e.g. for handling and transport of the string.

FIG. 4 shows a shingled solar cell string (2) for use in the assembly of a photovoltaic module (1) further comprising an adhesive foil (6) spanning the string (2) and positioned on the bottom side of one solar cell (3a) and on the top side of the overlapping solar cell (3b); in this case the adhesive foil (6) comprises the at least one interconnect (5) and connects the overlap (4), thereby mechanically connecting and positioning the shingled solar cells (3a, 3b) of the string (2). In one exemplary embodiment, the adhesive foil (6) comprising the interconnect (5) is an adhesive polymer foil (6) comprising one or more electrically conductive wires (10) (not shown here), that mechanically and electrically connect the shingled solar cells (3a, 3b).

FIG. 5 shows a specific embodiment of a solar cell (3) for producing a string (2) of solar cells (3a, 3b, 3c), wherein the overlap(s) (4) for connecting and shingling the solar cell comprise(s) a busbar (8) or wire ribbon (8) positioned perpendicular to the solar cell string direction (11, not shown) receiving current from the front and/or back fingers (9) collecting the solar cell current, which fingers are arranged parallel to the solar string direction (11). The busbar (8) or wire ribbon (8) may be positioned on the front (8a) or on the backside (8b) of the solar cell (3).

FIG. 6 shows a string production assembly line for a method of the present invention.

FIG. 6a shows positioning and connecting a first solar cell (3a) to an adhesive foil (6), e.g. the connection being done by heating the thermoadhesive foil (6); and positioning and connecting an interconnect material (5a) to the overlap region (4) of the first solar cell (3a).

FIG. 6b shows positioning and connecting a second solar cell (3b), e.g. the connection being done by heating the thermoadhesive foil (6), so that first and second solar cells (3a, 3b) form a shingled, foil-interconnected solar cell string (2) with the positive and negative electrodes of both solar cells (3a, 3b) being interconnected or in contact; and adding and connecting a further interconnect material (5b) to the further overlap region (4) of the second solar cell (3b).

FIGS. 6c and 6d show repetitions of positioning and connecting third and further solar cells (3b, 3c, 3d) to form a string (2) of shingled solar cells (3a, 3b, 3c, 3d), and optionally electrically connecting positive and negative electrodes of adjacent solar cells in their overlap regions (4). The interconnect materials (5a, 5b, 5c) may be electrically connected during the connecting of the solar cells (3a, 3b, 3c, 3d) to the adhesive foil (6), e.g. by the heat application for foil lamination, or at a separate later time point after the foiled solar cell string (2) has been handled, transported, assembled into a photovoltaic module, etc.

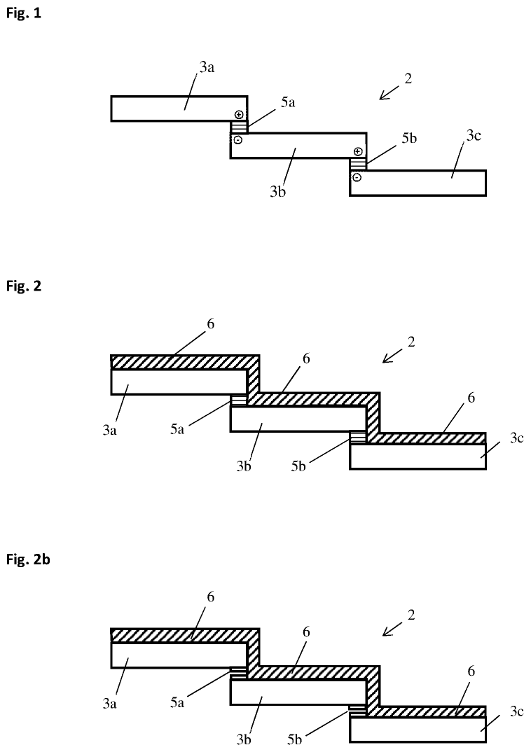

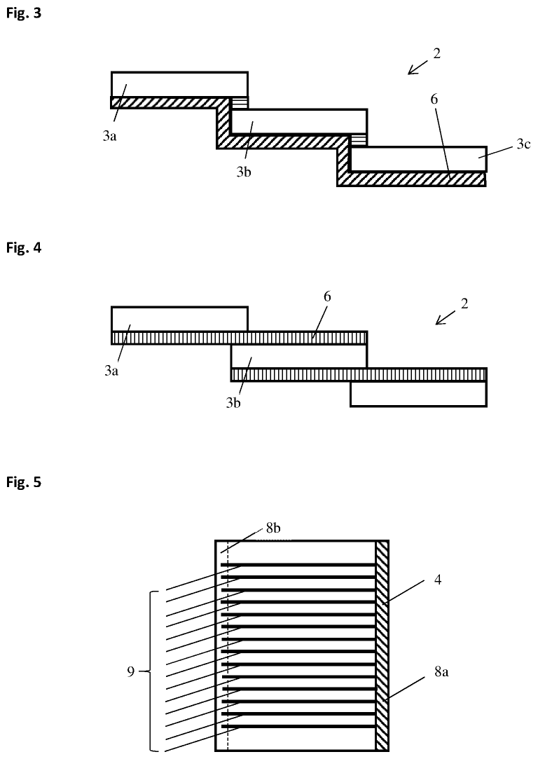

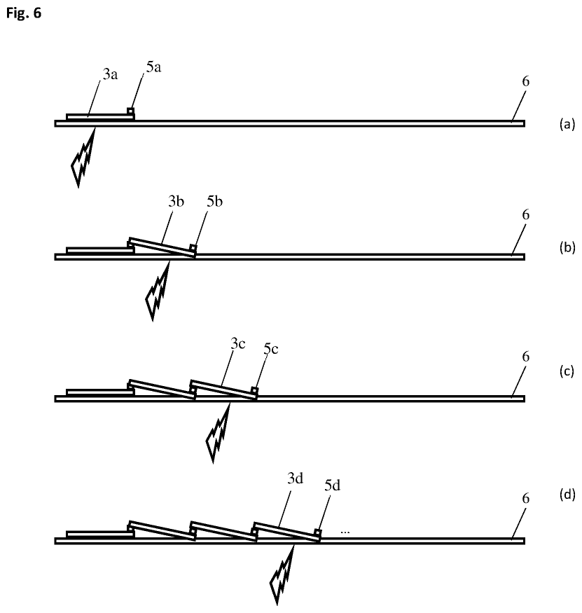

1. A solar cell string for use in a photovoltaic module, the string comprising:
(i) a string of at least two solar cells shingled in string direction, resulting in positive and negative electrode overlap,
(ii) at least one interconnect electrically connecting the positive and negative electrodes of the shingled solar cells, and
at least one thermoadhesive foil spanning at least part of the string and positioned on
(iii) a top side of one solar cell and on a bottom side of the overlapping solar cell,
wherein the thermoadhesive foil comprises the at least one interconnect and connects the overlap,
thereby mechanically connecting the shingled solar cells of the string.

2. The solar cell string of claim 1, wherein the interconnect a thermoadhesive electrically conductive foil.

3. The solar cell string of claim 1, wherein the overlap comprises a non-photovoltaically active zone of the at least two solar cells.

4. The solar cell string of claim 2, wherein the interconnect is in the form of a busbar configured to receive solar cell fingers arranged in string direction.

5. The solar cell string of claim 2, wherein the thermoadhesive foil comprises a polymer foil comprising at least one of an ethylene vinyl acetate, a thermoplastic silicone elastomer, a thermoplastic polyurethane, a polyethylene terephthalate, a thermoplastic polyfin elastomer, an ionomer, a polyvinylbutyral, a silicone, or a polyolefin.

6. The solar cell string of claim 1, wherein the thermoadhesive foil is positioned on a top side of one solar cell and on a bottom side of the overlapping solar cell, wherein the thermoadhesive foil comprises at least one electrically conductive element.

7. A method for the production of a solar cell string, the method comprising the steps of:
(a) providing at least two solar cells comprising overlap regions for forming a shingled solar cell string,
(b) providing at least one thermoadhesive foil comprising an interconnect for electrically connecting the positive and negative electrodes of the shingled solar cells,
(c) connecting a first solar cell to the adhesive foil,
(d) connecting the interconnect material on a first electrode region of the first solar cell,
(e) connecting a second solar cell to the thermoadhesive foil in a string direction so that the first and second solar cells overlap in shingle arrangement, resulting in positive and negative electrode overlap,
(f) optionally connecting the interconnect material on a further electrode of the second or further solar cell and connecting a third or further solar cell to the thermoadhesive foil in string direction so that the first, second, and further solar cells all overlap in shingle arrangement resulting in positive and negative electrode contact,
(i) electrically connecting the positive and negative electrodes of the shingled solar cells to produce the solar cell string of claim 1,
wherein the shingled solar cell string is electrically and mechanically connected in the overlap regions.

8. (canceled)

9. The method of claim 7, wherein the interconnect is a thermoadhesive electrically conductive foil.

10. The method of claim 9, wherein the overlap comprises a non-photovoltaically active zone of the at least two solar cells.

11. The method of claim 7, wherein the interconnect is in the form of a busbar configured to receive solar cell fingers arranged in string direction.

12. The method of claim 7, wherein the thermoadhesive foil comprises a polymer foil comprising at least one of an ethylene vinyl acetate, a thermoplastic silicone elastomer, a thermoplastic polyurethane, a polyethylene terephthalate, a thermoplastic polyfin elastomer, an ionomer, a polyvinylbutyral, a silicone, or a polyolefin, wherein the polymer foil is a thermoadhesive at a temperature in a range of 50 to 250° C.

13. The method of claim 12, wherein the thermoadhesive foil is positioned on a top side of one solar cell and on a bottom side of an overlapping solar cell, wherein the thermoadhesive foil comprises at least one electrically conductive elements.

14. The solar cell string of claim 2, wherein the thermoadhesive electrically conductive foil comprises a conductive element comprising metal wires.

15. The solar cell string of claim 14, wherein the metal wires are coated with at least one of an Ag comprising solder, a Sn comprising solder, a SnBi comprising solder, or an In comprising solder.

16. The solar cell string of claim 5, wherein the polymer foil is a thermoadhesive at a temperature in a range of 50 to 250° C.

17. The method of claim 9, wherein the metal wires are coated with at least one of an Ag comprising solder, a Sn comprising solder, a SnBi comprising solder, or an In comprising solder, and wherein the polymer foil is a thermoadhesive at a temperature in a range of 50 to 250° C.
